(19) United States
(12) Patent Application Publication
(10) Pub. No.: US 2025/0293006 A1
(43) Pub. Date: Sep. 18, 2025

(54) Apparatus and Method for Angle Control of Radicals, Neutral Atoms, and Molecules

(71) Applicant: Axcelis Technologies, Inc., Beverly, MA (US)

(72) Inventor: Glen GILCHRIST, Wingdale, NY (US)

(21) Appl. No.: 19/082,757

(22) Filed: Mar. 18, 2025

Related U.S. Application Data
(60) Provisional application No. 63/566,609, filed on Mar. 18, 2024.

(51) Int. Cl. H01J 37/32

(52) U.S. Cl. CPC H01J 37/32651; H01J 2237/3341; H01J 2237/3345

(57) ABSTRACT

Apparatuses and methods of operating the apparatus generally include a cryogenically cooled collimator that is cooled to capture and condense neutral atoms, radicals, and molecules generated in a plasma that contact surfaces thereof. The cryogenically cooled collimator includes a plurality of linear channels perpendicularly extending from the first planar side to a second planar side, wherein radicals that do not contact surfaces of the cryogenically cooled collimator are transmitted to a workpiece. Optionally, the apparatuses and methods may further include a radiation shield positioned in front of the cryogenically cooled collimator to prevent direct impingement of radiation onto the surface of the cryogenically cooled collimator. The cryogenically cooled collimator can be cooled to temperatures less than 300K during use.

### CROSS REFERENCE TO RELATED APPLICATIONS

This application claims the benefit of priority to U.S. Provisional Patent Application No. 63/566,609, filed Mar. 18, 2024, entitled “Apparatus and Method for Angle Control of Radicals, Neutral Atoms, and Molecules” which is incorporated by reference in its entirety herein.

### BACKGROUND

The present disclosure generally relates to integrated circuit fabrication and equipment, and more specifically, to plasma-based etching apparatuses and plasma-based etching methods for angle control of radicals, neutrals, and molecules.

Reactive ion etching (RIE) is a plasma-based dry etching technique used in microfabrication to precisely etch materials such as silicon, silicon dioxide, silicon nitride, silicon oxynitride, other dielectrics, titanium nitride and metals. It combines chemical etching (via reactive gas species) and physical etching (via ion bombardment) to achieve highly anisotropic patterns with fine resolution.

Several limitations associated with current RIB processes include, as examples, particle formation resulting from the polymerizing fluorocarbon etch chemistry; polymer deposition occluding the upper portion of features being etched such as in high aspect ratio vias for source/drains in Complementary Field Effect Transistors (“CFET”) and for contacts in backside power delivery networks (“BSPDN”); and pattern loading and pattern lagging (dimension dependent etch rate) effects caused by non-directional radicals.

Regarding particle formation resulting from the polymerizing fluorocarbon etch chemistry, fluorocarbon-based gases such as CF₄, CHF₃, C₄F₈, and CH(4-n)Fn are commonly used in RIE to etch silicon, silicon dioxide (SiO₂), and silicon nitride (Si₃N₄). These gases break down in the plasma to form a mixture of reactive species, including carbon-containing fragments (e.g., CxFy, CFx, etc.) that can contribute to polymer deposition on chamber walls, wafer surfaces, and electrostatic chucks. Over time, excessive polymer buildup can delaminate and generate particles. While fluorocarbon-based RIE is essential for selective and anisotropic etching, polymerization-induced particle formation remains a challenge.

Regarding etching of high aspect ratio vias, which is considered crucial for features such as vias in CFETs and contacts in BSPDN), polymer deposition from fluorocarbon-based RIE can pose a significant challenge by occluding the upper portions of the etched features. During deep etching, fluorocarbon gases like C₄F₈ or CHF₃ generate polymerized passivation layers that help control sidewall profiles and prevent excessive lateral etching. However, in high-aspect-ratio structures, excessive polymer accumulation near the feature opening can create a bottleneck effect, restricting ion transport and limiting the removal of volatile etch byproducts. This occlusion not only slows down the etch rate deeper into the feature but can also lead to incomplete etching, profile distortions, and feature pinch-off. As a result, critical electrical connections may suffer from increased resistance or even open-circuit failures. To mitigate this issue, process engineers carefully balance polymer deposition and removal by optimizing gas chemistry, such as incorporating controlled O₂ flow to modulate polymer thickness, adjusting RF bias to enhance ion directionality, or implementing periodic polymer removal steps within the etch sequence to maintain open feature profiles.

Still further, as noted above, pattern-dependent effects such as pattern loading and pattern lagging significantly impact etch uniformity and critical dimension (CD) control. These effects are primarily caused by non-directional reactive radicals, which influence the etch rate based on local feature density and aspect ratio. Understanding and mitigating these effects is crucial in etching applications such as CFET high-aspect-ratio vias and BSPDN contacts referenced above to ensure device performance and yield.

### BRIEF SUMMARY

Disclosed herein are apparatuses and methods of operating an apparatus for plasma based dry etching. In one or more embodiments, the apparatus includes a plasma source operable to generate a plasma within a plasma chamber enclosed by a chamber housing. The apparatus further includes a cryogenically cooled collimator including a planar body having a first planar side and a second planar side. The collimator includes a plurality of linear channels perpendicularly extending from the first planar side to the second planar side coupled to the chamber housing for delivering a beam comprising radicals generated by the plasma to a workpiece that is external to the plasma chamber through the linear channels. The cryogenically cooled collimator is configured to operate at a temperature for capturing and condensing any radicals impacting surfaces thereof. In one or more embodiments, the cryogenically cooled collimator is configured to be cooled to the temperature of less than 300K. In one or more embodiments, each of the plurality of linear channels have an aspect ratio greater than 5. The linear channels can have widths or diameters that change based on position on the cryogenically cooled collimator planar body. Optionally, the apparatus can further include a radiation shield within the plasma chamber and positioned in proximity to the cryogenically cooled collimator to prevent direct impingement of the beam onto the surfaces of the cryogenically cooled collimator. The radiation shield can be configured to be cooled during use. The radiation shield can be thermally connected to the cryogenically cooled collimator by a resistive link such that more cooling power is delivered to the collimator than to the radiation shield.

In one or more embodiments, a method for operating the apparatus includes generating a plasma within a plasma chamber, wherein the plasma chamber includes a cryogenically cooled collimator having a first planar side and a second planar side comprising a plurality of linear channels perpendicularly extending from the first planar side to the second planar side coupled to the plasma chamber. The cryogenically cooled collimator is cooled to a temperature effective to capture and condense neutral atoms, radicals, and molecules generated in the plasma that contact surfaces thereof. The transmitted radicals that do not contact the surfaces of the cryogenically cooled collimator and flow through the plurality of linear channels to a workpiece. Cooling the cryogenically cooled collimator to the temperature effective to capture and condense neutral atoms, radicals, and molecules is less than 300K. The flow of the radicals through the linear channels to the workpiece is at a non-zero angle of 30 to 85 degrees. In one or more embodiments, the method can further include coupling a radiation shield to the plasma chamber positioned in front of the cryogenically cooled collimator to prevent direct impingement of radiation from the plasma onto surfaces of the cryogenically cooled collimator. The radiation shield can be cooled during use. The cryogenically cooled collimator can be periodically thermally regenerated to remove captured gas film formed from impingement of the neutral atoms, radicals, and molecules onto the cooled collimator surfaces.

In one or more other embodiments, the apparatus includes a plasma source operable to generate a plasma within a plasma chamber enclosed by a chamber housing; a cryogenically cooled collimator including a planar body having a first planar side and a second planar side comprising a plurality of linear channels perpendicularly extending from the first planar side to the second planar side coupled to the chamber housing for delivering a beam comprising radicals generated by the plasma to a workpiece external to the plasma chamber through the linear channels, wherein the cryogenically cooled collimator is configured to operate at a temperature for capturing and condensing any radicals impacting surfaces thereof; and a radiation shield within the plasma chamber and positioned in proximity to the cryogenically cooled collimator to prevent direct impingement of the beam onto the surfaces of the cryogenically cooled collimator, wherein the radiation shield is thermally coupled to the cryogenically cooled collimator to provide cooling. An antenna is disposed external to the plasma chamber proximate to a dielectric window in the plasma chamber, wherein the antenna is electrically connected to a RF power supply to provide an alternating voltage to the antenna to generate the plasma source. The linear channels can have constant widths or diameters. In another embodiment, the linear channels have widths or diameters that change based on position on the cryogenically cooled collimator planar body.

These and other objects, advantages and features of the disclosure will become better understood from the detailed description of the disclosure that is described in conjunction with the accompanying drawings.

### BRIEF DESCRIPTION OF DRAWINGS

FIG. 1 is a schematic diagram of an exemplary reactive ion etching apparatus in accordance with one or more embodiments of the present disclosure;

FIG. 2 is a top plan view of a collimator in accordance with one or more embodiments of the present disclosure;

FIG. 3 is a cross-sectional view of the collimator of FIG. 2 taken along lines 3-3 in accordance with one or more embodiments of the present disclosure;

FIG. 4 is a schematic cross section diagram representative of reactive neutrals generated in a reactive ion apparatus and directed through a radiation shield and cryogenically cooled collimator towards a workpiece in accordance with one or more embodiments of the present disclosure; and

FIG. 5 is an enlarged view of a channel in the cryogenically cooled collimator detailing the possible flow paths of the neutral atoms, radicals and molecules generated in the plasma of the plasma chamber in accordance with several aspects of the present disclosure.

FIG. 6 schematically illustrates flow paths of the neutral atoms, radicals and molecules through a cryogenically cooled collimator in accordance with one or more embodiments of the present disclosure oriented at a non-zero angle of about 45° relative to the workpiece; and

FIG. 7 is a flowchart depicting a method in accordance with one or more embodiments of the present disclosure.

### DETAILED DESCRIPTION

The present disclosure is generally directed to overcoming many of the limitations of current reactive ion etch (RIE) apparatuses and methods for advanced semiconductor manufacturing by modifying the RIE apparatuses and methods by including the use of a cryogenically cooled collimator such that neutral atoms, radicals and molecules generated in the plasma that impact any surface of the cryogenically cooled collimator will be captured, as condensed species, by the cryogenically cooled collimator and thus not transmitted to the workpiece. Instead, only radicals, neutrals, and molecules of a neutral beam passing through the apertures of the cryogenically cooled collimator that do not contact any surface of the cryogenically cooled collimator will be transmitted to the workpiece, which may be a Si, SiC, GaN, GaAs, or like wafer, used for CMOS or other semiconductor integrated circuit fabrication. Advantageously, the cryogenically cooled collimator eliminates the issues associated with prior art RIE apparatuses and methods that suffered from, for example, particle formation resulting from the polymerizing fluorocarbon etch chemistry; polymer deposition occluding the upper portion of features being etched like high aspect ratio vias for CFET source/drains and BSPDN contacts; and pattern loading and pattern lagging (dimension dependent etch rate) effects caused by non-directional radicals. In this manner, the workpiece is exposed to a highly directional and uniform plasma to provide anisotropic etching. The integration of the cryogenically cooled collimator and associated methods of use eliminates the above limitations by eliminating randomly distributed radical angles and providing a highly uniform flux of radicals without exposing the wafer to polymerizing chemistry.

For the purposes of the description hereinafter, the terms “upper”, “lower”, “top”, “bottom”, “left,” and “right,” and derivatives thereof shall relate to the described structures, as they are oriented in the drawing figures. The same numbers in the various figures can refer to the same structural component or part thereof. Additionally, the articles “a” and “an” preceding an element or component are intended to be nonrestrictive regarding the number of instances (i.e., occurrences) of the element or component. Therefore, “a” or “an” should be read to include one or at least one, and the singular word form of the element or component also includes the plural unless the number is obviously meant to be singular.

Spatially relative terms, e.g., “beneath,” “below,” “lower,” “above,” “upper,” and the like, can be used herein for ease of description to describe one element or feature's relationship to another element(s) or feature(s) as illustrated in the figures.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

As used herein, the term “about” modifying the quantity of an ingredient, component, or reactant of the disclosure employed refers to variation in the numerical quantity that can occur, for example, through typical measuring procedures used for making component mixtures. Furthermore, variation can occur from inadvertent error in measuring procedures, differences in the manufacture, source, or purity of the ingredients employed to make the compositions or carry out the methods, and the like.

It will also be understood that when an element, such as a layer, region, or substrate is referred to as being “on” or “over” another element, it can be directly on the other element or intervening elements can also be present. In contrast, when an element is referred to as being “directly on” or “directly over” another element, there are no intervening elements present, and the element is in contact with another element.

The reactive ion apparatus and reactive ion processes in accordance with the present disclosure are not intended to be limited provided a cryogenically cooled collimator is integrated therein and any radicals, neutrals, and/or molecules generated in the reactive ion apparatus that contact any surfaces of the cryogenically cooled collimator are captured and condensed thereon and not transmitted to the workpiece whereas any radicals, neutrals, and/or molecules that pass through the apertures of the cryogenically cooled collimator without contact are uniformly directed to the workpiece. Accordingly, the present disclosure will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present disclosure may be practiced without these specific details. Further, the scope of the disclosure is not intended to be limited by the embodiments or examples described hereinafter with reference to the accompanying drawings but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling.

As noted above, the present disclosure is generally directed to RIE apparatuses and etching methods. As it well known in the art, RIE works by utilizing a combination of chemical reactions and physical ion bombardment to precisely remove material from a substrate. The process begins by introducing reactive gases, such as CF₄, SF₆, or Cl₂, into a relatively low-pressure chamber of about 1 to about 50 mTorr, where a strong RF (radio frequency) field generates a plasma. The plasma dissociates the gas molecules, creating highly reactive ions and radicals that chemically react with the material on the workpiece surface, forming volatile byproducts that are easily pumped away. Simultaneously, the electric field accelerates ions toward the workpiece, physically bombarding the surface and enhancing the etching process. This combination of chemical and physical etching ensures high anisotropy, meaning vertical sidewalls can be achieved with minimal undercutting, making RIE a crucial technique in microfabrication for creating high-resolution features in semiconductors, MEMS devices, and nanostructures.

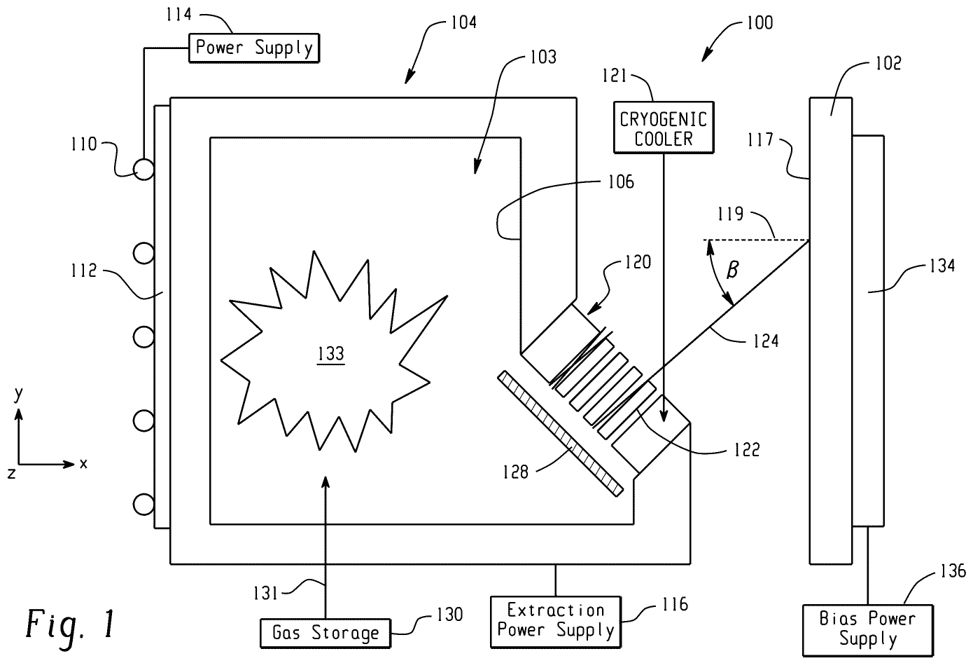

Turning now to FIG. 1, there is shown an exemplary RIE apparatus 100 for controlling the angle at which ions, reactive neutrals and molecules are directed toward a workpiece 102, e.g., a wafer. The RIE apparatus 100 may include a plasma chamber 103 of a plasma source 104, the plasma chamber 103 being defined by a chamber housing 106. In some embodiments, an antenna 110 is disposed external to the plasma chamber 103, proximate a dielectric window 112. The dielectric window 112 may also form one of the walls that define the plasma chamber 103. The antenna 110 may be electrically connected to a power supply 114 (e.g., RF power supply), which supplies an alternating voltage to the antenna 110. Although non-limiting, the voltage may be at a frequency of, for example, 2 MHz or more. While the dielectric window 112 and antenna 110 are shown on one side of the plasma chamber 103, other embodiments are also possible. The chamber housing 106 may be made of a conductive material, such as graphite, and may be biased at an extraction voltage, such as by extraction power supply 116. The extraction voltage may be, for example, 1 kV. Other voltages are possible within the scope of the disclosure.

The RIE apparatus 100 includes an opening defined by a cryogenically cooled collimator 120 having a plurality of linear channels 122 (i.e., apertures) of a constant width, which are used to control the angular distribution of ions reaching the surface of the workpiece 102. A primary function of the cryogenically cooled collimator 120 is to improve anisotropic etching by filtering out ions traveling at oblique angles and capture any radicals impacting any surface of the collimator as condensed species, which are not transmitted to the workpiece 102. During use, the cryogenically cooled collimator 120 is generally cooled by a cryogenic cooler 121 such that any radicals, neutral atoms, and/or molecules generated from the particular gas used to form the plasma condense onto any surfaces of the cryogenically cooled collimator 120 that are contacted such that a highly direction radical flux is transmitted to the workpiece, Generally, the cryogenically cooled collimator is cooled during use to a temperature configured to capture and condense any radicals impacting a surface thereof such that only radicals passing through the channel without contact of any surfaces are transmitted to the workpiece, i.e., below room temperature, which is less than about 300K. In one or more embodiments, the cryogenically cooled collimator is cooled during use to a temperature less than 200K and in still other embodiments, the cryogenically cooled collimator is cooled during use to a temperature less than 100K such as for example, 65K. Cryogenic cooling can be achieved by evaporative cooling, conduction, rapid expansion, or adiabatic demagnetization.

The cryogenically cooled collimator 120 forms a portion of the chamber housing 106 defining the plasma chamber 103. Although non-limiting, the cryogenically cooled collimator 120 may be disposed on an opposite side of the plasma chamber 103 from the dielectric window 112. The capture capacity for the cryogenically cooled collimator is generally proportional to the surface area in striking range of the radicals and the thickness of the captured gas film formed by the radicals impacting the collimator surfaces before the channels 122 become blocked. In contrast, the plasma radicals not captured by the collimator are generally referred to as the neutral beam emittance, which can be determined by the aspect ratio of z/y of the beam channels 122. Mathematically, the neutral beam emittance can be defined as Θₑ=±tan⁻¹(z/y).

By way of example, a channel 122 having an aspect ratio of 5 (AR=5, Θₘₐₓ) will have a neutral beam emittance equal to ±tan⁻¹(⅕) or ±11.3°, which means the range of beam angles is 22.6°. In contrast, collimator channels 122 having a higher aspect ratio will result in a decreased neutral beam emittance. For example, channels having an aspect ratio of 10 (AR=10, Θₘₐₓ) will have a neutral beam emittance of (±tan⁻¹( 1/10) or ±5.7°, which means the range of beam angles is 11.4°.

In one or more embodiments, the aspect ratio is greater than 5. In other embodiments, the aspect ratio is greater than 10. Higher aspect ratio channels will result in more frequent downtime to provide for thermal rapid regeneration of the collimator since the portion of the neutral atoms, radicals and molecules impacting surfaces within the channel 122 condense on those surfaces.

In certain embodiments, the cryogenically cooled collimator 120 may be constructed from an insulating material, such as quartz, sapphire, alumina or a similar insulating material. The use of an insulating material may allow recombination of radicals to form molecules. In other embodiments, the cryogenically cooled collimator 120 may be constructed of a conducting material. The cryogenically cooled collimator 120 may have a separate power supply (not shown) for modulating a temperature of the cryogenically cooled collimator 120 relative to the chamber housing 106 and/or the interior of the plasma chamber 103.

As shown, the workpiece 102 may be disposed proximate the cryogenically cooled collimator 120, outside the plasma chamber 103. In some embodiments, the cryogenically cooled collimator 120 may be oriented at a non-zero angle ‘B’ (e.g., approximately) 45° relative to a perpendicular 119 extending from a main surface 117 of the workpiece 102. As will be described in greater detail herein, the orientation of the cryogenically cooled collimator 120 and the plurality of channels 122 causes one or more highly directional radical beams 124 to impact the workpiece 102 at the non-zero angle (or within an acceptable+/−deviation amount from the non-zero angle). Throughout this disclosure, extraction angles are referenced to the perpendicular 119, which extends normal to a plane defined by the main surface 117 of the workpiece 102. Thus, an extraction angle of 0° refers to a path that is perpendicular to the main surface 117 of the workpiece 102, while an extraction angle of 90° is a path parallel to the main surface 117 of the workpiece 102. Emittance, or angular distribution, of the radical beams 124, refers to beam spread in and out of the page and up and down on this page that is in two axes orthogonal to the velocity vector of the radical beams, 124 (i.e., in the x, y-direction with respect to the workpiece 102).

In operation, the antenna 110 may be powered using a RF signal from the power supply 114 so as to inductively couple energy into the plasma chamber 103. This inductively coupled energy excites the feed gas introduced from a gas storage container 130 via a gas inlet 131, thus generating a plasma 133. The particular gases are not intended to be limited. Exemplary gases include, without limitation fluorocarbon gases such as CF₄, CHF₃, C₄F₈, and CH₍₄₋ₙ₎Fn, wherein n is an integer from 1 to 3, and other halogen containing gases such as F₂, NF₃, SF₆, Cl₂, CF₂Cl₂, CC₁₄, BCl₃, Br₂, HBr, and the like. While FIG. 1 shows antenna 110, it will be appreciated that other plasma generators may also be used with the present disclosure, e.g., inductively coupled plasma generators, capacitive coupled plasma generators, magnetron plasma generators, microwave plasma generators, helicon wave plasma generators and the like.

The plasma 133 within the plasma chamber 103 may be biased at the voltage being applied to the chamber housing 106 by the extraction power supply 116. The workpiece 102, which may be disposed on a platen 134, may be electrically biased by a bias power supply 136. The difference in potential between the plasma 133 and the workpiece 102 causes ions in the plasma 133 to be accelerated through the cryogenically cooled collimator 120 in the form of one or more ion beams and toward the workpiece 102, In other words, positive ions are attracted toward the workpiece 102 when the voltage applied by the extraction power supply 116 is more positive than the bias voltage applied by the bias power supply 136. Thus, to extract positive ions, the chamber housing 106 may be biased at a positive voltage, while the workpiece 102 is biased at a less positive voltage, ground or a negative voltage. In other embodiments, the chamber housing 106 may be grounded, while the workpiece 102 is biased at a negative voltage. In yet other embodiments, the chamber housing 106 may be biased at a negative voltage, while the workpiece 102 is biased at a more negative voltage. In yet another embodiment, both the chamber housing 106 and workpiece 102 may be grounded and ions generated in the plasma will have only thermal velocity, typically less than 1 eV.

In one or more embodiments, the RIE apparatus can further include an optically dense radiation shield 128 configured to shield the cryogenically cooled collimator 120 from direct impingement of the plasma radiation generated during plasma processing on the cryogenically cooled collimator 120. For example, the radiation shield can be thermally connected to the collimator by a resistive link such that more cooling power is delivered to the collimator than to the radiation shield. The radiation shield 128 has the same potential as the plasma radiation and can be spaced apart from the collimator at a distance to prevent direct impact of the plasma radiation onto the cryogenically cooled collimator 120. In one or more embodiments, the spacing can be about 1 millimeter. Optionally, during use the radiation shield 128 can be actively cooled by an external source or passively cooled by the cryogenically cooled collimator 120. In the present disclosure, the radiation shield is configured to increase operating lifetime of the cryogenically cooled collimator 120 by shielding the collimator from direct contact and also by improving distribution of the plasma species to the cryogenically cooled collimator 120 and through its linear channels 122. Suitable radiation shields can be formed of an inert materials such as ceramics including quartz, sapphire, boron nitride and the like, metals such as molybdenum, tungsten, and stainless steel, dielectrics, or the like. In some embodiments, the radiation shield may include a polytetrafluoroethylene coating.

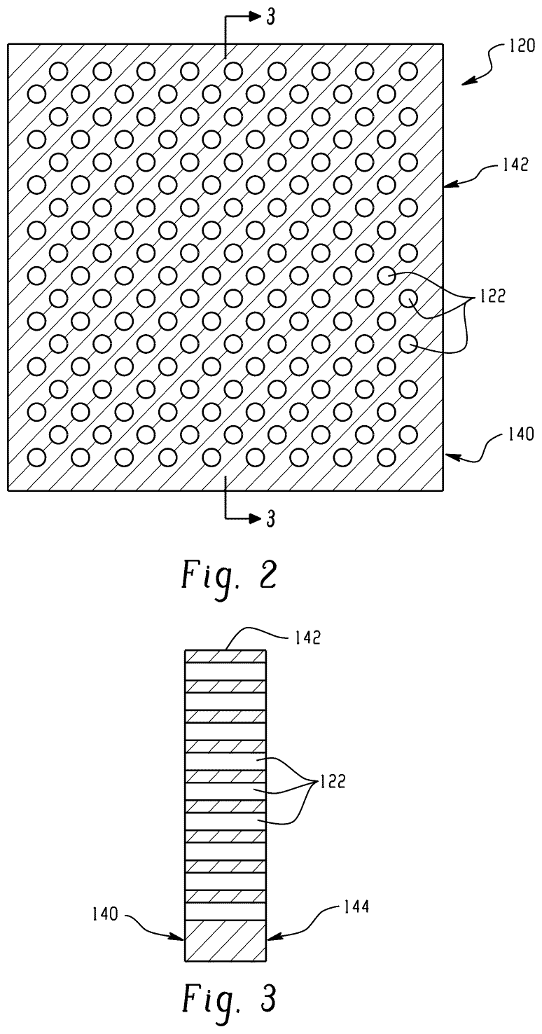

Turning now to FIGS. 2 and 3, there is depicted a top-down view and a cross-sectional view, respectively, of an exemplary collimator 120 including a plurality of linear apertures 122 extending through the collimator 120. The apertures are depicted as circular and having a constant diameter but it should be apparent that other geometric shapes can be used. Likewise, the shape and dimensions are not intended to be limited and may vary. Still further, the linear channels can have widths or diameters that change with position on the collimator main body. Also, the channels can be uniformly spaced about the main body as shown or can have varying densities and arrangements of the channels as may be desired for different applications.

The first side 140 of the main body 142 of the cryogenically cooled collimator 120 may be disposed within the plasma chamber 103, while the second side 144 may be disposed outside the plasma chamber 103. The channels 122 are operable to direct reactive neutral species like radicals and atoms including, for example, H, N, O, F, Cl, and Br and ions toward the workpiece 102 at a predetermined angle (e.g., 45°).

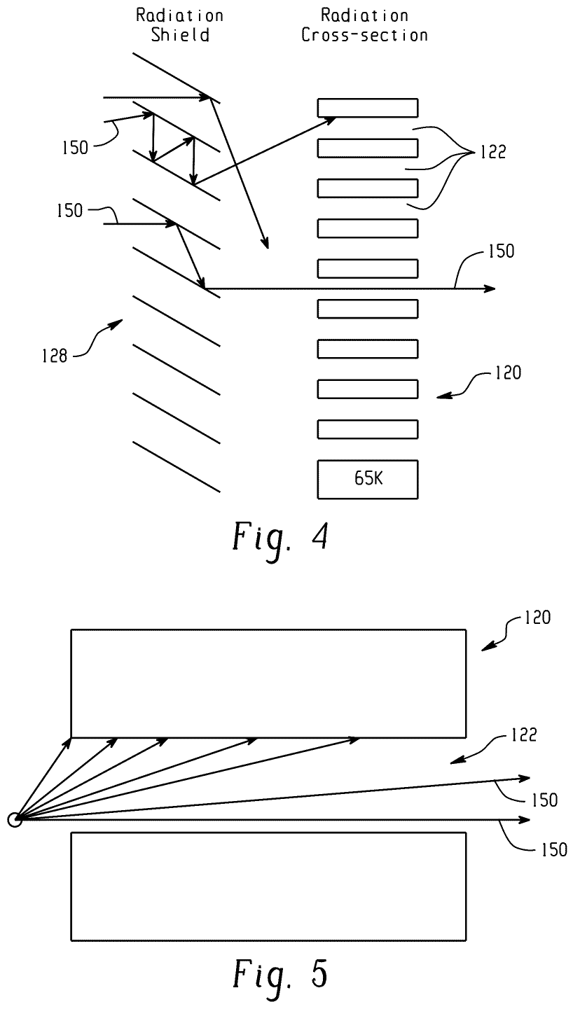

As generally shown in FIG. 4, the reactive neutrals 150 travel in straight lines at a given thermal velocity (e.g., 400-2000 m/s) until they collide with other molecules, radicals, atoms or structure surfaces. For example, the reactive neutrals may collide with surfaces of the radiation shield 128 to prevent direct impingement onto surfaces of the cryogenically cooled collimator 120 and/or with other ions or reactive neutrals. Then, the reactive neutrals may collide with surfaces defined by cryogenically cooled surfaces of the collimator 120. Radical velocity vector collisions between reactive neutrals including radicals and atoms with the cryogenically cooled collimator surfaces will be captured and condensed thereon such that only those reactive neutrals free from contact with the cryogenically cooled collimator surfaces passing directly through the channels 122 of the cryogenic cooled collimator 120 will be transmitted to the workpiece 102 as shown.

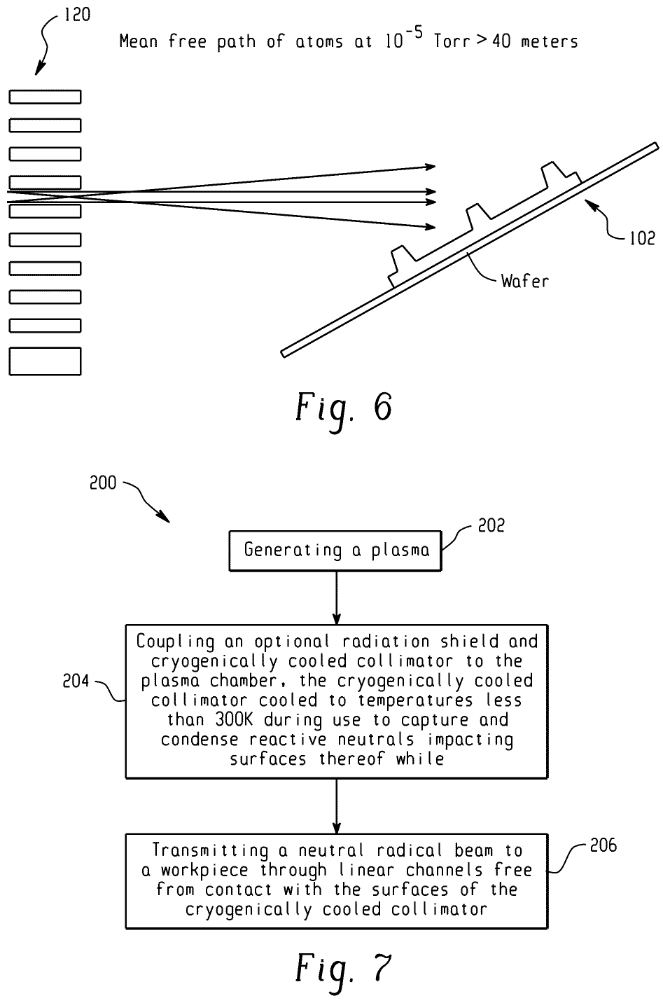

In FIGS. 5-6, there are expanded cross-sectional views of the collimator showing the direction of neutral atoms, radicals and molecules generated in the plasma chamber and directed to the workpiece. As shown, the neutral atoms, radicals and molecules travel in a straight path but are not uniform in terms of direction such that a portion of the neutral atoms, radicals and molecules impact surfaces within the channel 122 and a portion flow through without contact with any surfaces of the channel. The neutral atoms, radicals, and molecules striking any surface of the cryogenically cooled collimator will be absorbed i.e., captured, the collimator. As previously discussed, the portion passing through the channel is generally dependent on the aspect ratio associated with channels. The lower the aspect ratio, the greater the dispersion of the beam angle. In contrast, the higher the aspect ratio, the lower the dispersion is associated with the beam angle. However, a balance with respect to the aspect ratio and the number of channels over a given area should be taken into account so that a desired operating lifetime, i.e., cryogenic capture capacity, before thermal regeneration is needed for the cryogenically cooled collimator can be achieved. By way of example, an exemplary collimator can be a 4×4 cm square that is 1 cm thick with 162 uniformly disposed apertures (as shown in FIG. 2) having a 0.2 cm diameter. From this, the total area of the collimator surfaces can be calculated by first determining the total area of the aperture side walls, which is 162×π×0.2×1=101.8 cm². If the process gas is fluorine (F₂), for example, the mass for a thickness equal to half of the aperture diameter of 0.05 cm=101.8 cm²×0.05 cm×1.5 g/cm³=7.64 g (solid)=9002 cm³ F₂ gas=150 process hours at 1 sccm or 4.48×10¹⁷ neutrals/second before thermal regeneration is needed to remove the solids from the channel surfaces. Cleaning can be effected by thermal regeneration.

In contrast, increasing the cryogenically cooled collimator size by 8 times to 32 cm×32 cm provides full wafer coverage and increases the cryogenic capture capacity by 82 to 489 g or 9608 process hours before cryogenic regeneration would be needed.

Turning to FIG. 7, a method 200 according to embodiments of the disclosure will be described. At block 202, the method 200 may include generating a plasma within a plasma chamber of a plasma source. At block 204, the method 200 may include coupling an optional radiation shield and cryogenically cooled collimator to the plasma chamber, the cryogenically cooled collimator including a plurality of linear channels of constant diameter and cooled to temperatures less than 300K during use to capture and condense reactive neutrals impacting surfaces thereof. In some embodiments, the cryogenically cooled collimator is oriented at a non-zero angle, wherein the one or more radical beams include fluorine radicals. The non-zero angle may be between 30°-85°. In some embodiments, a ratio of channel length to channel diameter is greater than 5:1, preferably 10:1.

In some embodiments, each channel of the plurality of channels has an entrance and an exit, wherein the channel width is constant, e.g. if the channel has a circular shape, the diameter is constant from the entrance to the exit.

At optional block 206, the method 200 may further include delivering the one or more radical beams to the workpiece to etch the workpiece. For example, the workpiece may include high aspect ratio vias for source/drains in Complementary Field Effect Transistors (“CFET”) or contacts for backside power delivery networks (“BSPDN”). The highly directional beam as a consequence of the cryogenically cooled collimator capturing and condensing beams contacting the collimator surfaces can be used to prevent excessive polymer accumulation near the feature opening, for example.

Embodiments described herein may have many advantages. For example, directed reactive ion etching is more precisely controlled by the channel diameter of the cryogenically cooled collimator.

The foregoing descriptions of the preferred embodiments of the disclosure have been presented for purposes of illustration and description. It is not intended to be exhaustive or to limit the disclosure to the precise forms disclosed. Obvious modifications or variations are possible in light of the above teachings. The embodiments were chosen and described to provide the best illustration of the principles of the disclosure and its practical applications to thereby enable one of ordinary skill in the art to utilize the disclosure in various embodiments and with various modifications as are suited to the particular use contemplated. All such modifications and variations are within the scope of the disclosure as determined by the appended claims when interpreted in accordance with the breadth to which they are fairly, legally and equitably entitled.

What is claimed:

1. An apparatus comprising:
a plasma source operable to generate a plasma within a plasma chamber enclosed by a chamber housing; and
a cryogenically cooled collimator including a planar body having a first planar side and a second planar side comprising a plurality of linear channels perpendicularly extending from the first planar side to the second planar side coupled to the chamber housing for delivering a beam comprising radicals generated by the plasma to a workpiece external to the plasma chamber through the linear channels, wherein the cryogenically cooled collimator is configured to operate at a temperature for capturing and condensing any radicals impacting surfaces thereof.

2. The apparatus of claim 1, further comprising a radiation shield within the plasma chamber and positioned in proximity to the cryogenically cooled collimator to prevent direct impingement of the beam onto the surfaces of the cryogenically cooled collimator.

3. The apparatus of claim 1, wherein the radiation shield is configured to be cooled during use.

4. The apparatus of claim 1, wherein the cryogenically cooled collimator is configured to be cooled to the temperature of less than 300K.

5. The apparatus of claim 1, wherein the cryogenically cooled collimator is configured to be cooled to the temperature of less than 200K.

6. The apparatus of claim 1, wherein the cryogenically cooled collimator is configured to be cooled to the temperature of less than 100K.

7. The apparatus of claim 1, wherein each of the plurality of linear channels have an aspect ratio greater than 5.

8. The apparatus of claim 1, wherein each of the plurality of linear channels have an aspect ratio greater than 10.

9. The apparatus of claim 1, wherein the linear channels have widths or diameters that change based on position on the cryogenically cooled collimator planar body.

10. The apparatus of claim 2, wherein the radiation shield is thermally connected to the cryogenically cooled collimator by a resistive link such that more cooling power is delivered to the collimator than to the radiation shield.

11. A method of operating an apparatus, the method comprising:
generating a plasma within a plasma chamber, wherein the plasma chamber comprises a cryogenically cooled collimator having a first planar side and a second planar side comprising a plurality of linear channels perpendicularly extending from the first planar side to the second planar side coupled to the plasma chamber;
cooling the cryogenically cooled collimator to a temperature effective to capture and condense neutral atoms, radicals, and molecules generated in the plasma that contact surfaces thereof; and
transmitting the radicals that do not contact the surfaces of the cryogenically cooled collimator and flow through the plurality of linear channels to a workpiece.

12. The method of claim 11, wherein cooling the cryogenically cooled collimator to the temperature effective to capture and condense neutral atoms, radicals, and molecules is less than 300K.

13. The method of claim 11, wherein cooling the cryogenically cooled collimator to the temperature effective to capture and condense neutral atoms, radicals, and molecules is less than 200K.

14. The method of claim 11, wherein cooling the cryogenically cooled collimator to the temperature effective to capture and condense neutral atoms, radicals, and molecules is less than 100K.

15. The method of claim 11, wherein the flow of the radicals through the linear channels to the workpiece is at a non-zero angle of 30 to 85 degrees.

16. The method of claim 11, further comprising coupling a radiation shield to the plasma chamber and positioned in front of the cryogenically cooled collimator to prevent direct impingement of radiation from the plasma onto surfaces of the cryogenically cooled collimator.

17. The method of claim 16 further comprising cooling the radiation shield during use.

18. The method of claim 9 further comprising periodically thermally regenerating the cryogenically cooled collimator to remove captured gas film formed from impingement of the neutral atoms, radicals, and molecules onto the cooled collimator surfaces.

19. The method of claim 11, wherein each of the plurality of linear channels have a constant width or a diameter.

20. An apparatus comprising:
a plasma source operable to generate a plasma within a plasma chamber enclosed by a chamber housing; and
a cryogenically cooled collimator including a planar body having a first planar side and a second planar side comprising a plurality of linear channels perpendicularly extending from the first planar side to the second planar side coupled to the chamber housing for delivering a beam comprising radicals generated by the plasma to a workpiece external to the plasma chamber through the linear channels, wherein the cryogenically cooled collimator is configured to operate at a temperature for capturing and condensing any radicals impacting surfaces thereof;
a radiation shield within the plasma chamber and positioned in proximity to the cryogenically cooled collimator to prevent direct impingement of the beam onto the surfaces of the cryogenically cooled collimator, wherein the radiation shield is thermally coupled to the cryogenically cooled collimator to provide cooling; and
an antenna disposed external to the plasma chamber proximate to a dielectric window in the plasma chamber, wherein the antenna is electrically connected to a RF power supply to provide an alternating voltage to the antenna to generate the plasma source.

21. The apparatus of claim 20, wherein the linear channels have constant widths or diameters.

22. The apparatus of claim 20, wherein the linear channels have widths or diameters that change based on position on the cryogenically cooled collimator planar body.
